(19) United States
(12) Patent Application Publication
(10) Pub. No.: US 2011/0134957 A1
(43) Pub. Date: Jun. 9, 2011

(54) Low Chirp Coherent Light Source

(75) Inventors: Hui Su, Arcadia, CA (US); Genzao Zhang, Ottawa (CA); Henry A. Blauvelt, San Marino, CA (US)

(73) Assignee: Emcore Corporation, Albuquerque, NM (US)

(21) Appl. No.: 12/632,625

(22) Filed: Dec. 7, 2009

(51) Int. Cl. H01S 5/026

(52) U.S. Cl. 372/50.22

(57) ABSTRACT

A coherent light source having a semiconductor laser resonator and an optical amplifier which amplifies coherent light emitted by the semiconductor laser resonator in response to current injection, in which the amount of current injected into the semiconductor laser is controlled for conformity with a chirp requirement of an optical communication system. The optical amplifier, which introduces no chirp, may be controlled to match an optical power requirement of the optical communication system. A heater may be provided to introduce a low frequency chirp in order to suppress interferometric intensity noise and unwanted second-order effects such as stimulated Brillouin Scattering. The optical amplifier may be monolithically formed with the semiconductor laser resonator, with separate electrodes provided for injecting current into the semiconductor laser resonator and the optical amplifier.

### FIELD OF THE INVENTION

The invention relates to generally a coherent light source having low chirp. The invention has particular, but not exclusive, relevance to light sources for fiber optic communication systems.

### BACKGROUND OF THE INVENTION

Dispersion management is one of the key techniques for optical fiber communication, for example around the 1.5 micron telecommunications window. Dispersion is caused by optical signals with different wavelengths propagating at different speeds in the optical fiber. Therefore, an original optical pulse having components at multiple optical frequencies will spread while propagating through an optical fiber, resulting in distortion of the optical pulse or smearing of two optical pulses at the time of detection.

A single-mode distributed feedback semiconductor laser has a number of attractive properties as a coherent light source for optical communication, including a very narrow spectral linewidth in the order of 1 Megahertz. Although external modulation schemes have been employed, it is preferred to use direct current modulation since the external modulation schemes generally require higher voltages and increased device footprint. Direct current modulation has, however, the effect of introducing chirp both due to a difference in the lasing frequency at different injection current levels resulting from a variation in the optical refraction index (static or adiabatic chirp) and due to transient effects occurring at changes of injection current level (transient chirp). A typical laser diode may have a chirp factor of 100 MHz/mA, resulting in an optical spectrum of 3 Gigahertz under 30 mA direct current modulation. For analog optical communications, this introduces severe RF signal distortion.

Over communication links having a fixed distance, pre-distortion circuits may be used to compensate for dispersion. However, for low-cost communications it is preferred to have a single module operating over a range of distances (for example 0 to 20 km for FTTx systems) instead of having fixed length communication links. Accordingly, there is a desire for a laser diode with reduced chirp.

A disadvantage of reducing the chirp introduced by a coherent light source is that the reduced linewidth is an increase in interferometric intensity noise and nonlinear effects such as Stimulated Brillouin Scattering (SBS). In the article “A Method for Reducing Multipath Interference Noise” by S. L. Woodward and T. E. Darcie, IEEE Photonics Technology Letters, Vol. 6, No. 3, March 1994, it is proposed to reduced multipath interference intensity noise by dithering the laser frequency of a DFB laser diode by several Gigahertz at kilohertz frequencies (see also U.S. Pat. No. 5,373,385). The comparatively low modulation frequency allows the modulation to be achieved by temperature modulation as a result of varying the current supplied to a resistive heater formed on the DFB laser diode.

In the article “Single Contact Monolithically Integrated DFB Laser Amplifier” by R. T. Sahara et al., IEEE Photonics Technology Letters, Vol. 14, No. 7, July 2002, in order to achieve high-power operation it is proposed to integrate monolithically a distributed feedback (DFB) laser diode and an optical amplifier.

### SUMMARY OF THE INVENTION

It is an object of the invention to provide a coherent light source having low-chirp properties.

This and other objects are provided by a coherent light source having a semiconductor laser resonator and an optical amplifier which amplifies coherent light emitted by the semiconductor laser resonator in response to current injection, in which the amount of current injected into the semiconductor laser is controlled for conformity with a chirp requirement of an optical communication system. The optical amplifier, which introduces minimal chirp, may be controlled to match an optical power requirement of the optical communication system.

This and other objects are also provided by a coherent light source having a semiconductor laser resonator and an optical amplifier which amplifies coherent light emitted by the semiconductor laser in response to current injection, in which a heater is provided to modulate the temperature of the semiconductor laser resonator. Such temperature modulation results in a corresponding variation of the laser wavelength, resulting in an increase in the linewidth of the emitted coherent light. This increase in the linewidth reduces multipath interference intensity and undesirable non-linear effects such as SBS.

This and other objects are further provided by a semiconductor laser having a monolithic gain region, having a first section forming a laser resonator and a second section forming an optical amplifier, and first and second electrodes arranged for injecting current into the first and second sections respectively. This facilitates the injection of a first current into the laser resonator to produce coherent light satisfying a desired chirp requirement, and a second current into the optical amplifier to satisfy an optical power requirement.

An embodiment of the invention provides a coherent light source which is well suited for an analog optical fiber communication system, such as CATV, in that it exhibits a dynamic bandwidth over 0-2 GHz with little variation in gain profile.

### BRIEF DESCRIPTION OF THE DRAWINGS

FIG. 1 schematically shows a side view of a coherent light source forming a first embodiment of the invention;

FIG. 2 is a graph showing measured chirp factors for a plurality of coherent light sources as illustrated in FIG. 1;

FIG. 3 is a graph showing the S21 gain parameter over a range of frequencies for a coherent light source as illustrated in FIG. 1;

FIG. 4 is a graph showing the optical spectrum of a coherent light source as illustrated in FIG. 1 having a 0.5% output reflectance;

FIG. 5 is a graph showing the optical spectrum of a coherent light source as illustrated in FIG. 1 having a 4.5% output reflectance;

FIG. 6 schematically shows a side view of a coherent light source forming a second embodiment of the invention;

FIG. 7 schematically shows a side view of a coherent light source forming a third embodiment of the invention; and

FIG. 8 schematically shows an optical communication system employing a coherent light source according to the invention.

### DETAILED DESCRIPTION OF THE INVENTION

### First Embodiment

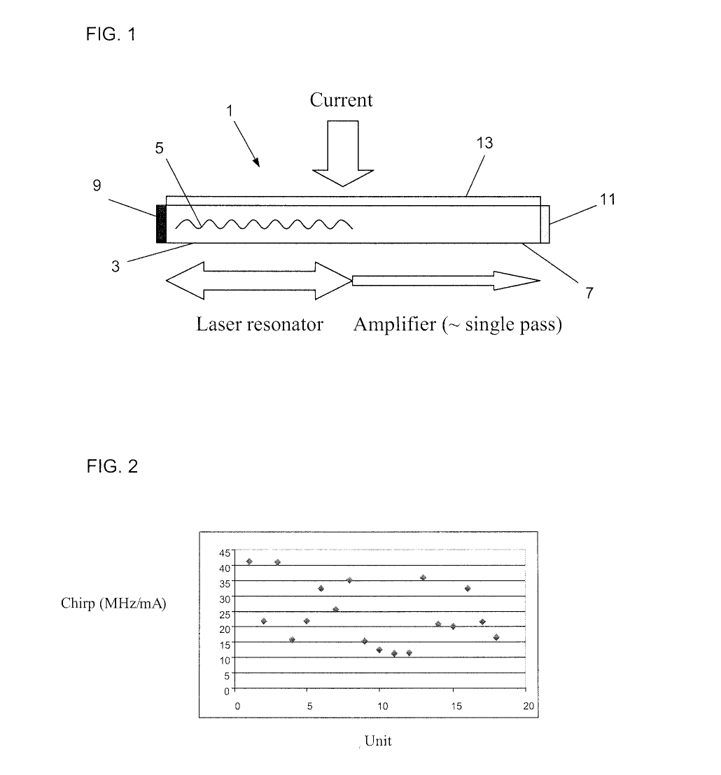

As shown in FIG. 1, a first embodiment of the invention is formed by a coherent light source 1 having a semiconductor laser resonator 3, including a distributed feedback reflector 5, monolithically integrated with a semiconductor optical amplifier 7. The coherent light source 1 has a ridge (not shown in FIG. 1) formed in a conventional manner to define an elongated waveguide, and a gain region which extends in a conventional manner along the length of the coherent light source 1. The semiconductor laser resonator 3 is formed at one side of the waveguide and the semiconductor optical amplifier 7 is formed at the other side of the waveguide. Coatings are placed at the end of the coherent light source 1 adjacent to the semiconductor laser resonator 3 to form a highly-reflective mirror 9 at the lasing wavelength, while coatings are placed at the end of the coherent light source 1 adjacent to the semiconductor optical amplifier 7 to form an anti-reflection coating 11 at the lasing wavelength. Current is injected into the gain region along the entire length of the coherent light source 1 via an electrode 13.

In this embodiment, the length of the coherent light source is 750 microns. The semiconductor laser resonator 3 extends over half the length (i.e. 375 microns) of the coherent light source 1 and the semiconductor optical amplifier 7 extends along the other half of the length (i.e. 375 microns) of the coherent light source 1. It will be appreciated that the coherent light source 1 may have other lengths, and the ratio of the length of the laser resonator 3 relative to the optical amplifier 7 is a design choice.

The semiconductor optical amplifier 7 shows negligible adiabatic chirp (the dominant chirp for CATV and other analog communication systems) for RF modulation up to 1 Gigahertz. Accordingly, the current injected into the semiconductor optical amplifier causes negligible chirp while the coherent light source 1 still generates the necessary optical modulation index (OMI) for analog communication applications. In this embodiment, the current injected into the semiconductor laser resonator is controlled to achieve a chirp factor which matches a target chirp requirement for an optical communication system. The optical amplifier provides the required optical output power. It will be appreciated that the absolute and relative lengths of the semiconductor laser resonator 3 and the semiconductor optical amplifier 7, and the strength of the grating 5, can be adjusted to achieve the desired performance parameters.

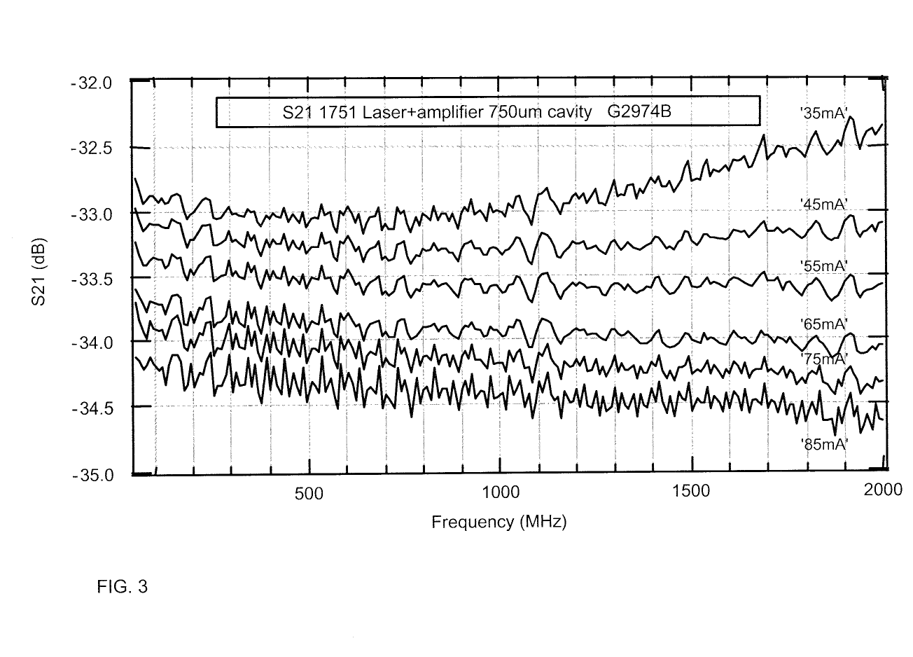

FIG. 2 shows the chirp factors for eighteen different coherent light sources 1 according to the first embodiment of the invention. It can be seen that the chirp factor varies from approximately 10 MHz/mA to approximately 40 MHz/mA, which compares favorably with the typical chirp factor of 100 MHz/mA for a DFB laser diode. FIG. 3 shows the S21 gain parameter at different injection currents over the wavelength range 0-2 GHz. This shows that the coherent light source 1 has a dynamic bandwidth suitable for analog optical communication applications, with the variation of the S21 gain factor over that bandwidth being in the order of 0.5 dB.

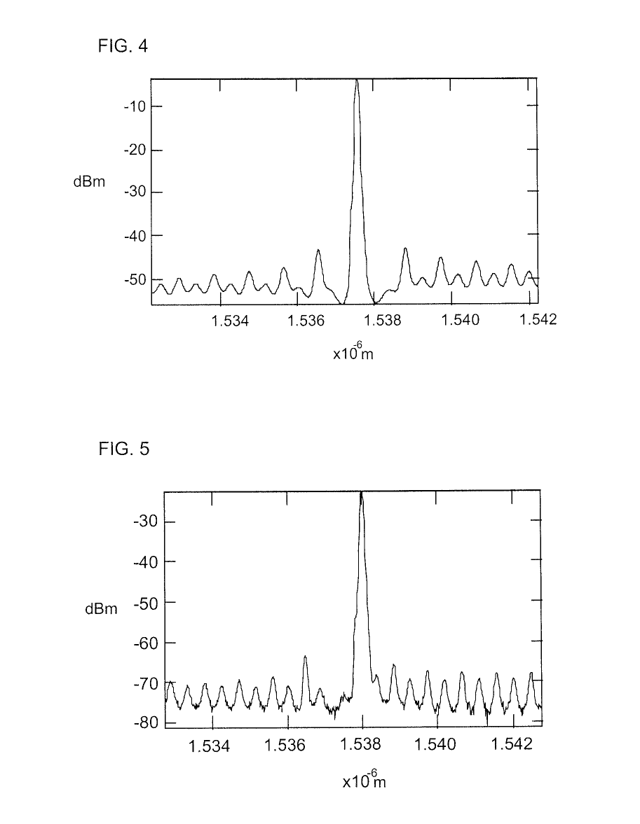

FIG. 4 shows the optical output spectrum for the coherent laser device 1 with an anti-reflection coating 11 having a reflectivity of 0.5%, whereas FIG. 5 shows the optical output spectrum for the coherent light source 1 with an anti-reflection coating 11 having a reflectivity of 4.5%. To each side of the principal lasing wavelength, side peaks are formed consisting of smaller peaks located between higher peaks. The smaller peaks come from resonance between the anti-reflection coating 11 and the laser resonator 3.

### Second Embodiment

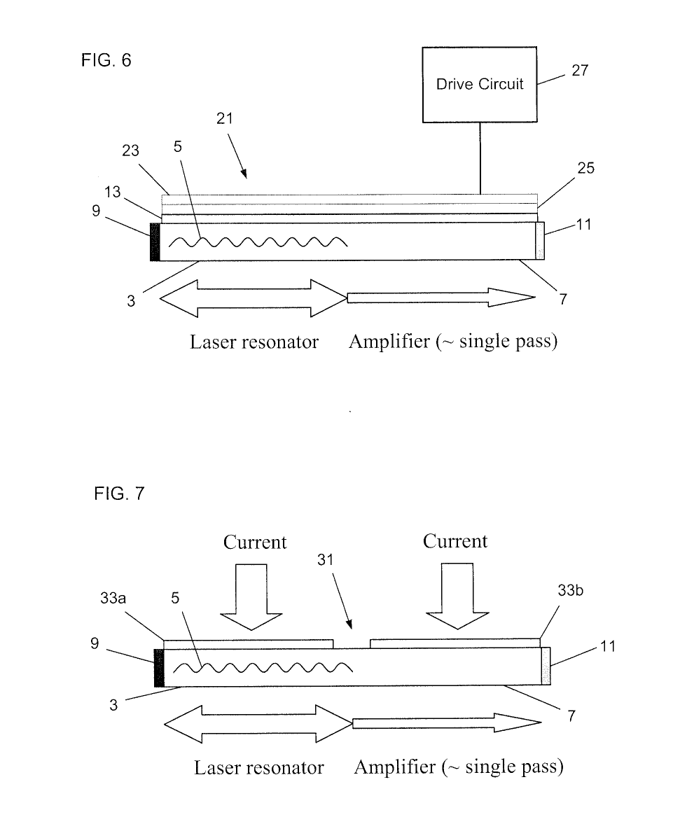

While the coherent light source 1 of the first embodiment exhibits low chirp, the reduced linewidth may lead to unwanted interferometric intensity noise and second-order effects such as SBS. As shown in FIG. 6, a second embodiment of the invention is formed by a coherent light source 21 having a resistive heater 23 added to the top of the ridge defining the waveguide. In FIG. 6, features which are the same as corresponding features of the first embodiment have been referenced using the same reference numerals and will not be described in detail again. The resistive heater 23 is electrically insulated from the electrode 13 by a dielectric layer 25.

In this embodiment, the resistive heater 23 is formed by a layer of Ti/NiCr/Pt. A drive circuit 27 supplies a drive signal to the resistive heater 23 which varies the temperature of the semiconductor laser resonator 3, thereby varying the laser wavelength. In particular, the variation of temperature introduces a thermal chirp typically with a frequency in the range of 10 to 100 kHz. This variation in the laser wavelength suppresses SBS and interferometric intensity noise without severely compromising the performance of for example, CATV channels between 50 MHz and 1 GHz.

### Third Embodiment

As discussed above, in the first embodiment a common electrode injects current both into the laser resonator 3 and the optical amplifier 7. As shown in FIG. 7, a third embodiment of the invention is formed by a coherent light source 31 having separate electrodes 33a, 33b respectively associated with the semiconductor laser resonator 3 and the semiconductor optical amplifier 7. In FIG. 7, features which are the same as corresponding features of the first embodiment have been referenced with the same reference numerals and will not be described in detail again.

Providing separate electrodes 33a, 33b allows greater controllability of the optical properties of the coherent light source 31. In particular, by allowing different currents to be injected into the semiconductor laser resonator 3 and the semiconductor optical amplifier 7, a single device can be used to achieve many different combinations of chirp factor and optical power output. Alternatively, it may be desirable to supply a constant current to the semiconductor laser resonator 3 and a modulated current only to the semiconductor optical amplifier 7.

### Modifications and Further Embodiments

In the first to third embodiments, the semiconductor laser resonator 3 and the semiconductor optical amplifier 7 are monolithically integrated and share a common gain region. Such an arrangement is advantageous both with respect to device footprint and simplicity of driving. However, such monolithic integration is not essential. For example, the semiconductor laser could be coupled to a fiber amplifier.

The first to third embodiments are semiconductor devices. The composition of the semiconductors used will depend on the desired lasing wavelength, as is well known to those skilled in the art. Around 1550 nm, InP based systems using one or more of InGaAs, InGaAsP and AlGaInP may be used.

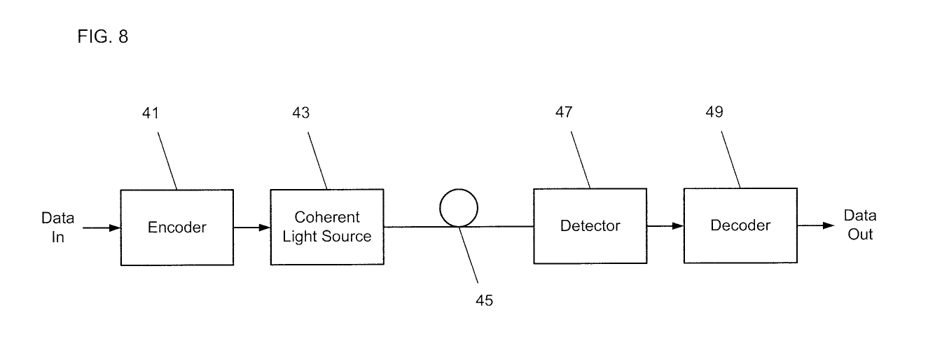

The coherent light sources discussed above are well suited to optical fiber communication systems, including analog systems such as CATV. FIG. 8 schematically shows the main components of such a system. A data signal is input to an encoder 41 which converts the data signal into a suitable format for transmission. The output of the encoder 43 is input to a coherent light source 43 according to the present invention, and the optical signal output by the coherent light source 43 is input to one end of an optical fiber 45. The other end of the optical fiber 45 is input to a detector 47 which converts the optical signal conveyed along the optical fiber 45 into a corresponding electrical signal, which is input to a decoder 49 which recovers the original data signal.

It will be appreciated that the above embodiments are described for exemplary purposes only, and many modifications will be apparent to a person of ordinary skill in the art.

1. A coherent light source for an optical communication system, the coherent light source comprising:
a semiconductor laser resonator operable to produce coherent light in response to current injection; and
an optical amplifier operable to amplify coherent light output by the semiconductor laser resonator,
wherein the amount of current injected into the semiconductor laser resonator is controlled so that the coherent light output by the coherent light source has a chirp which conforms with a chirp requirement of the optical communication system.

2. A coherent light source according to claim 1, wherein the optical amplifier comprises a semiconductor optical amplifier pumped by current injection.

3. A coherent light source according to claim 2, wherein the semiconductor laser resonator and the semiconductor optical amplifier share a common monolithic gain region.

4. A coherent light source according to claim 3, comprising a common electrode for the semiconductor laser resonator and the semiconductor optical amplifier, wherein current is injected into the semiconductor laser resonator and the semiconductor optical amplifier via the common electrode.

5. A coherent light source according to claim 3, further comprising a first electrode associated with the semiconductor laser resonator and a second electrode associated with the optical amplifier, wherein a first current is injected into the semiconductor laser resonator via the first electrode and a second current is injected into the semiconductor laser via the second electrode.

6. A coherent light source according to claim 1, further comprising a heater operable to modulate the temperature of the semiconductor laser resonator.

7. A coherent light source according to claim 6, wherein the heater comprises a resistive layer formed on the semiconductor laser resonator.

8. A coherent light source according to claim 7, wherein the resistive layer comprises a layer of Ti/NiCr/Pt.

9. A coherent light source according to claim 6, further comprising a drive circuit for supplying a drive current to said heater so as to vary a laser wavelength of the semiconductor laser resonator.

10. A coherent light source according to claim 9, wherein the drive circuit is arranged to supply said alternating drive current so as to vary said laser wavelength of the semiconductor laser resonator with a frequency in the range from 10 to 100 kHz.

11. A coherent light source comprising:
a semiconductor laser resonator operable to produce coherent light in response to current injection; and
an optical amplifier operable to amplify coherent light output by the semiconductor laser,
wherein the semiconductor laser resonator comprises a heater operable to modulate the temperature of the semiconductor laser resonator.

12. A coherent light source according to claim 11, wherein the heater comprises a resistive layer formed on the semiconductor laser resonator.

13. A coherent light source according to claim 12, wherein the resistive layer comprises a layer of Ti/NiCr/Pt.

14. A coherent light source according to claim 11, further comprising a drive circuit for supplying a drive current to said heater so as to vary a laser wavelength of the semiconductor laser resonator.

15. A coherent light source according to claim 14, wherein the drive circuit is arranged to supply said alternating drive current so as to vary said laser wavelength of the semiconductor laser resonator with a frequency in the range of 10 to 100 kHz.

16. A semiconductor laser comprising:
a monolithic gain region operable to produce optical gain in response to current injection, the gain region having:
a first section forming a laser resonator; and
a second section operable to amplify light emitted by the laser resonator;
a first electrode arranged for injecting a first current into the first section; and
a second electrode arranged for injecting a second current into the second section.

17. A semiconductor laser according to claim 16, wherein the first section comprises a grating arranged to provide distributed feedback at the lasing wavelength.

18. A semiconductor laser according to claim 16, further comprising a heater operable to modulate the temperature of the gain region.

19. A semiconductor laser according to claim 18, wherein the heater comprises a resistive layer formed on the semiconductor laser.

20. A semiconductor laser according to claim 16, further comprising a drive circuit for supplying a drive current to said heater so as to vary a laser wavelength of the semiconductor laser,
wherein the drive circuit is arranged to supply said alternating drive current so as to vary said laser wavelength of the semiconductor laser with a frequency in the range of 10 to 100 kHz.
